(19) United States
(12) Patent Application Publication
(10) Pub. No.: US 2010/0247975 A1
(43) Pub. Date: Sep. 30, 2010

(54) Method for producing double-sided evaporation film, double-sided evaporation film intermediate, double-sided evaporation film and magnetic recording medium support

(75) Inventors: Hideaki Takeuchi, Kanagawa (JP); Junji Nakada, Kanagawa (JP)

Correspondence Address: AKERMAN SENTERFITT, 8100 BOONE BOULEVARD, SUITE 700, VIENNA, VA, 22182-2683, US

(73) Assignee: FUJIFILM Corporation, Tokyo (JP)

(21) Appl. No.: 12/659,362

(22) Filed: Mar. 5, 2010

(30) Foreign Application Priority Data
Mar. 31, 2009 (JP) 2009-088502

(51) Int. Cl. G11B 5/73; C23C 16/44

(52) U.S. Cl. 428/846.2; 427/209

(57) ABSTRACT

A method for producing a double-sided evaporation film by forming metal-containing evaporation films on both surfaces of a non-magnetic plastic substrate film by an evaporation system with an evaporation drum, includes, in the following order: forming a metal-containing evaporation film on a first surface of the substrate film; forming an organic substance film on the metal-containing evaporation film; and forming a metal-containing evaporation film on a second surface of the substrate film, the second surface being opposite to the first surface.

### CROSS-REFERENCE TO RELATED APPLICATIONS

This application claims the benefit of Japanese Patent Application JP 2009-088502, filed Mar. 31, 2009, the entire content of which is hereby incorporated by reference, the same as if set forth at length.

### FIELD OF THE INVENTION

The present invention relates to a method for producing a double-sided evaporation film, a double-sided evaporation film intermediate and a double-sided evaporation film, concerned with a double-sided evaporation film producing method excellent in production efficiency and an intermediate thereof and a double-sided evaporation film. Particularly it relates to a method capable of producing a magnetic recording medium support excellent in dimensional stability with good efficiency and high quality while suppressing a bad influence caused by variations in temperature and humidity and variations in tension in a drive for use of a magnetic recording medium, an intermediate of a magnetic recording medium support and a magnetic recording medium support produced by the method or obtained from the intermediate.

### BACKGROUND OF THE INVENTION

Magnetic recording media for recording computer data as external recording media have been investigated in the recent years eagerly in the field of magnetic tapes with the advance of popularization of personal computers, work stations, etc. In practical use of magnetic recording media for such purposes, improvement in recording capacity has been strongly requested in order to satisfy increase in capacity and reduction in size of recording devices particularly in combination with reduction in size and increase in information processing capacity of computers.

The track width at recording/reproduction on/from magnetic recording media has a tendency to be narrowed in order to achieve a higher recording density and a larger recording capacity. In addition, in the field of magnetic tapes, reduction in thickness of magnetic tapes has advanced to make high density recording feasible, so that a large number of magnetic tapes with a total thickness of not larger than 10 μm have appeared. Magnetic recording media are however susceptible to change of temperature, humidity, tension or the like at custody or running if the magnetic recording media become thin.

That is, for example, at recording/reproduction on/from a magnetic recording/reproducing system using a linear recording method, a magnetic head must move in a widthwise direction of a magnetic tape to select any track but high accuracy is required for controlling the position of the magnetic head relative to the magnetic tape as the track width becomes narrowed. Even if an MR head and a fine-grain magnetic substance are used to improve the S/N ratio to thereby achieve a narrow track width, there is a possibility that the reproducing head will not read a recorded track because the magnetic recording medium is deformed in accordance with change of temperature and humidity in a use environment and change of tension in a drive. Therefore, higher dimensional stability of the medium than ever is required. In such a high density magnetic recording medium, both higher-grade dimensional stability and mechanical strength than those of the conventional medium are required in order to keep recording/reproduction stable.

As described above, to obtain high-grade dimensional stability of a magnetic recording medium, it is conceivable that a non-magnetic support such as a plastic substrate film used in the magnetic recording medium is restrained from being affected by change of temperature and humidity and change of tension in a drive. To restrain the non-magnetic support from being affected by change of temperature and humidity, it is conceivable that films high in water vapor barrier characteristic are provided in both surfaces of the support. To restrain the non-magnetic support from being affected by change of tension in a drive, it is conceivable that a film with a high Young's modulus is provided.

For example, a metal-containing evaporation film of a metal or a metal compound such as metal oxide or metal nitride can be used as such a film with high water vapor barrier characteristic and a high Young's modulus.

Formation of a metal-containing evaporation film on a surface of a plastic substrate film is generally performed by an evaporation system with an evaporation drum (also referred to as cooling can) (e.g. JP-A-2000-17440). To form metal-containing evaporation films on both surfaces of a substrate film, it is general that the evaporation film is first formed on the whole of one surface (hereinafter referred to as surface A) and the evaporation film is then formed on the whole of the other surface (hereinafter referred to as surface B).

If the evaporation film is first formed on the surface A, there is however a problem that the substrate film cannot be brought into sufficient contact with the evaporation drum of the evaporation system at the time of evaporation on the surface B. Consequently, transmission of heat from the substrate film to the evaporation drum is worsened. In the formation of the evaporation film on the substrate film by the evaporation system with the evaporation drum, heat due to evaporation is radiated to the evaporation drum (cooling can) so that a good-quality evaporation film can be obtained while the plastic substrate film is prevented from being thermally damaged by a heat load such as heat radiated from a vaporization source at the time of evaporation, heat of condensation at the time of evaporation, etc. Accordingly, if the substrate film cannot be brought into sufficient contact with the evaporation drum, heat due to evaporation cannot be radiated to the evaporation drum (cooling can) so that the quality of an evaporation film formed is worsened by thermal damage of the plastic substrate film.

As for measures against this disadvantage, the velocity of conveyance of the substrate film in the evaporation system is slowed to elongate the time of contact between the evaporation drum and the substrate film so that heat due to evaporation can be radiated to the evaporation drum (cooling can) to some degree even when the substrate film cannot be brought into sufficient contact with the evaporation drum. There is however a problem that slowing the velocity of conveyance of the substrate film causes lowering of aimed production efficiency of the double-sided evaporation film.

On the contrary, a technique for bringing a substrate film into close contact with a cooling evaporation roller (evaporation drum) by electrically charging the substrate film before evaporation of a metal evaporation film or by applying a voltage between the metal evaporation film and the cooling evaporation roller after evaporation of the metal evaporation film has been described in JP-A-2000-17440 and JP-A-2005-146401. There is known a technique for providing an insulating film of a dielectric substance or the like on a surface of an evaporation drum and enhancing the degree of contact by applying a bias voltage between the evaporation drum and an evaporation film formed only on the surface A of a substrate film at the time of evaporation on the surface B.

When the insulating film of a dielectric substance or the like is provided on the surface of the evaporation drum, transmission of heat at the time of initial evaporation of the evaporation film on the surface A side is however worsened to cause lowering of production efficiency. For this reason, there is a problem that it is difficult to provide one system which can serve as an evaporation system for forming the evaporation film on the surface A side and also as an evaporation system for forming the evaporation film on the surface B side.

### SUMMARY OF THE INVENTION

An object of the invention is to provide a technique for forming high-quality metal-containing evaporation films on both surfaces of a plastic substrate film to overcome the problem in the background art.

The inventors of the present invention have found as a result of dedicated investigation that the problem in the background art can be overcome by use of the following configuration.

That is, the configuration of the invention is as follows.

(1) A method of producing a double-sided evaporation film by forming metal-containing evaporation films on both surfaces of a non-magnetic plastic substrate film by an evaporation system with an evaporation drum, including the steps of: forming a metal-containing evaporation film on one surface (hereinafter referred to surface A) of the substrate film; forming an organic substance film on the metal-containing evaporation film; and forming a metal-containing evaporation film on the other surface (hereinafter referred to as surface B) of the substrate film.
(2) A method of producing a double-sided evaporation film according to the paragraph (1), wherein a voltage is applied between the metal-containing evaporation film formed on the surface A and the evaporation drum when the metal-containing evaporation film is formed on the surface B.
(3) A method of producing a double-sided evaporation film according to the paragraph (1), wherein the surface B of the substrate film before evaporation is irradiated with electron beams and the evaporation drum is charged with a positive electric potential when the metal-containing evaporation film is formed on the surface B.
(4) A method of producing a double-sided evaporation film according to the paragraph (2) or (3), wherein the metal-containing evaporation film on the surface A has conducting characteristic such that its sheet resistance is not higher than 10⁵Ω.
(5) A method of producing a double-sided evaporation film according to any one of the paragraphs (1) to (4), wherein the metal-containing evaporation film is a film made of a metal or a metal compound.
(6) A method of producing a double-sided evaporation film according to the paragraph (1), wherein the organic substance film is formed before the metal-containing evaporation film on the surface A comes into contact with the evaporation drum on a path of conveyance of the substrate film in the evaporation system.
(7) A method of producing a double-sided evaporation film according to the paragraph (1) or (6), wherein the organic substance film is formed in such a manner that an organic compound is vapor-deposited on the metal-containing evaporation film on the surface A.
(8) A method of producing a double-sided evaporation film according to the paragraph (7), wherein the organic compound vapor-deposited on the metal-containing evaporation film on the surface A is an ultraviolet ray- or electron beam-polymerizable organic compound which is irradiated with ultraviolet rays or electron beams after the organic compound is vapor-deposited.
(9) A double-sided evaporation film intermediate including a metal-containing evaporation film and an organic substance film provided successively on one surface (surface A) of a non-magnetic plastic substrate film in order in view from the substrate film side.
(10) A double-sided evaporation film including metal-containing evaporation films provided on both surfaces of a non-magnetic plastic substrate film respectively, and an organic substance film further provided on the metal-containing evaporation film on one surface (surface A) side.
(11) A double-sided evaporation film produced by a method described in any one of the paragraphs (1) to (8).
(12) A method of producing a double-sided evaporation film described in any one of the paragraphs (1) to (8), wherein the method is a method for producing a magnetic recording medium support.
(13) A magnetic recording medium support produced by a method described in any one of the paragraphs (1) to (8).

According to the method of the invention, because a metal-containing evaporation film is formed on one surface (surface A) of a substrate film and then an organic substance film is formed on the metal-containing evaporation film on the surface A side before a metal-containing evaporation film is formed on the other surface (surface B) of the substrate film, the substrate film can be brought into sufficient contact with an evaporation drum so that the plastic substrate film is prevented from being thermally damaged by a heat load such as heat radiated from a vaporization source at the time of evaporation, heat of condensation at the time of evaporation, etc. even when the substrate film is conveyed at a relatively high velocity. Consequently, the quality of the formed evaporation film becomes good.

Moreover, because a voltage is applied between the metal-containing evaporation film formed on the surface A side of the substrate film and the evaporation drum at the time of formation of the metal-containing evaporation film on the surface B of the substrate film or electron beam irradiation is applied on the surface B of the substrate film and the evaporation drum is electrically charged with a positive electric potential before evaporation of the metal-containing evaporation film on the surface B, the evaporation drum and the metal-containing evaporation film on the surface A side generate a capacitor-like electrostatic state through the organic substance film to thereby improve adhesion and contact between the substrate film and the evaporation drum.

According to the method for producing a double-sided evaporation film according to the invention, a double-sided evaporation film having high-quality metal-containing evaporation films on both surfaces of a plastic substrate film can be produced efficiently.

### BRIEF DESCRIPTION OF THE DRAWINGS

FIG. 1 is a view schematically showing an example of an evaporation system used in a method of producing a double-sided evaporation film according to the invention.

FIG. 2 is a view schematically showing another example of the evaporation system used in the method of producing a double-sided evaporation film according to the invention.

FIG. 3 is a view schematically showing a further example of the evaporation system used in the method of producing a double-sided evaporation film according to the invention.

### DETAILED DESCRIPTION OF THE INVENTION

A method of producing a double-sided evaporation film according to the invention will be described below in detail.

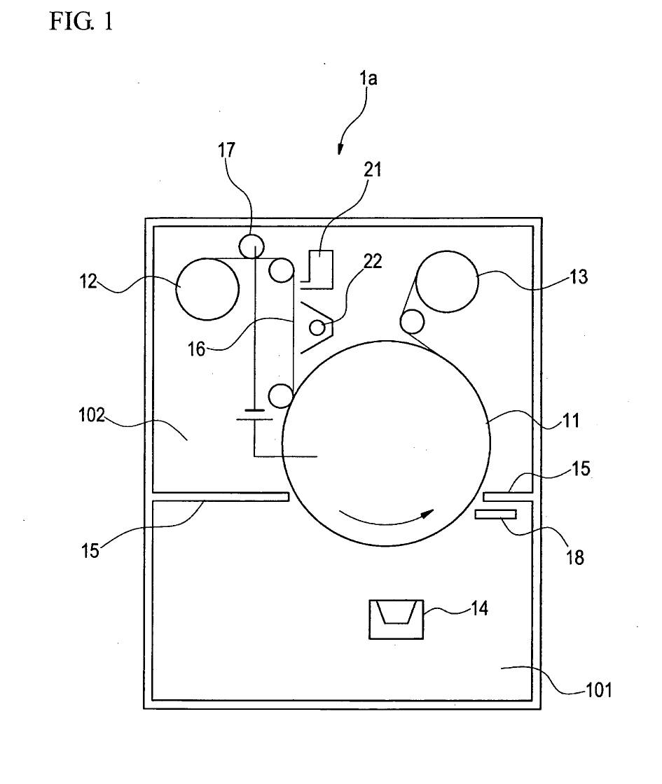

An evaporation system used in the method of producing a double-sided evaporation film according to the invention is not particularly limited as long as the evaporation system has an evaporation drum. For example, as shown in FIGS. 1 to 3, an evaporation chamber 101 and an evaporation target substrate film container (hereinafter also simply referred to as container) 102 are provided in the inside of a housing of the evaporation system. An evaporation source 14 and a gas introduction hole 18 are provided in the inside of the evaporation chamber 101. An evaporation drum 11, a substrate film feed roll 12 and a substrate film take-up roll 13 are provided in the inside of the container 102. The evaporation chamber 101 and the container 102 are isolated from each other by a partition 15 so that an evaporation component is prevented from entering the inside of the container 102. The evaporation drum 11 is disposed to be partially located in the inside of the evaporation chamber 101 so that an evaporation film can be formed on a substrate film 16 put on a part of the evaporation drum 11. In the aforementioned system, the substrate film 16 is conveyed from the feed roll 12 so as to be wound on a surface of the evaporation drum 11 and taken up by the take-up roll 13.

For example, evaporation/formation of metal-containing evaporation films on both surfaces of the substrate film 16 by the evaporation system having the aforementioned basic structure is as follows.

First, a metal-containing evaporation film is evaporated/formed on one surface (surface A) of the substrate film 16. After the substrate film 16 with the evaporation film evaporated/formed on the surface A side is taken up by the take-up roll 13, a roll of the substrate film 16 with the metal-containing evaporation film evaporated/formed on the surface A side is demounted from the take-up roll 13 and mounted on the feed roll 12. The substrate film 16 is then conveyed so as to be wound on the evaporation drum 11 while the surface A side abuts on the evaporation drum 11. The substrate film 16 is then taken up by the take-up roll 13. On this occasion, a metal-containing evaporation film is evaporated/formed on the other surface (surface B) of the substrate film 16.

Moreover, in the method of producing a double-sided evaporation film according to the invention, after the metal-containing evaporation film is formed on the surface A side of the substrate film 16, an organic substance film is formed on the metal-containing evaporation film on the surface A side before formation of the metal-containing evaporation film on the surface B side of the substrate film 16.

The time of formation of the organic substance film is not particularly limited as long as the time is after formation of the metal-containing evaporation film on the surface A side of the substrate film 16 and before formation of the metal-containing evaporation film on the surface B side of the substrate film 16. For example, the organic substance film may be formed after formation of the metal-containing evaporation film on the surface A side and before taking-up of the substrate film 16 by the take-up roll 13 or the organic substance film may be formed by another method, system, etc. after formation of the metal-containing evaporation film and after taking-up of the substrate film 16 by the take-up roll 13. Preferably, the organic substance film is formed after feeding of the substrate film 16 from the feed roll 12 and before the surface A side comes into contact with the surface of the evaporation drum 11.

The method of forming the organic substance film is not particularly limited. Although it is possible to use various methods such as a method of applying or spraying and drying a coating composition of a high-molecular compound dissolved in a solvent or a method of evaporating a high-molecular compound at a high temperature, it is preferable from the viewpoint of production efficiency that a method of evaporating an ultraviolet ray- or electron beam-polymerizable organic compound (monomer) and then irradiating the organic compound with ultraviolet rays or electron beams or a method of co-evaporating two or more kinds of polymerizable compounds (monomers) is used when the organic substance film is formed after feeding of the substrate film 16 from the feed roll 12 and before the surface A comes into contact with the surface of the evaporation drum 11 in the evaporation system.

FIG. 1 shows the structure of the system in the case where an ultraviolet ray- or electron beam-polymerizable monomer is evaporated and then irradiated with ultraviolet rays or electron beams after feeding of the substrate film 16 from the feed roll 12 and before the surface A comes into contact with the surface of the evaporation drum 11 in the evaporation system. A monomer evaporation source 21 and an ultraviolet ray or electron beam irradiation unit 22 are disposed between the feed roll 12 and the evaporation drum 11 in a path of conveyance of the substrate film 16.

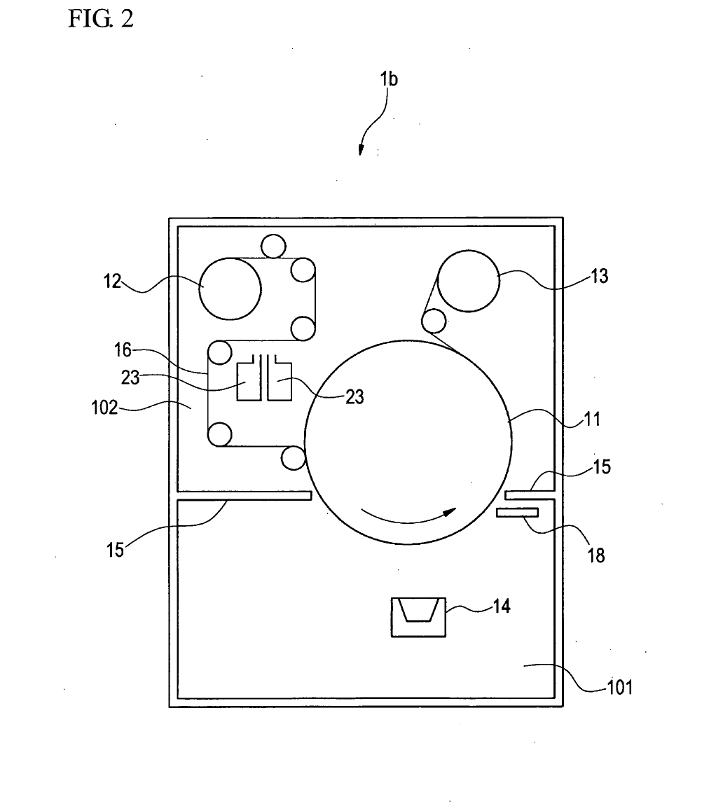

FIG. 2 shows the structure of the system in the case where two or more kinds of monomers are co-evaporated. Evaporation sources (a plurality of kinds of monomer evaporation sources) 23 for evaporating the two or more kinds of monomers are disposed between the feed roll 12 and the evaporation drum 11 in a path of conveyance of the substrate film 16.

The ultraviolet ray- or electron beam-polymerizable monomer and the two or more kinds of monomers to be co-evaporated are particularly limited and can be selected suitably from publicly known, publicly used and commonly known monomers in accordance with various production qualifications and specifications in the producing method according to the invention.

In the method of producing a double-sided evaporation film according to the invention, it is preferable that a voltage is applied between a metal-containing evaporation film and the evaporation drum 11 when the metal-containing evaporation film is formed on the surface B side of the substrate film 16 after formation of the aforementioned organic substance film. The method and system structure for applying a voltage between the metal-containing evaporation film and the evaporation drum 11 are not particularly limited. For example, as shown in FIG. 1, one of guide rollers 17 is formed to have a surface made of a conductive material so that a voltage is applied between the guide roller 17 and the evaporation drum 11.

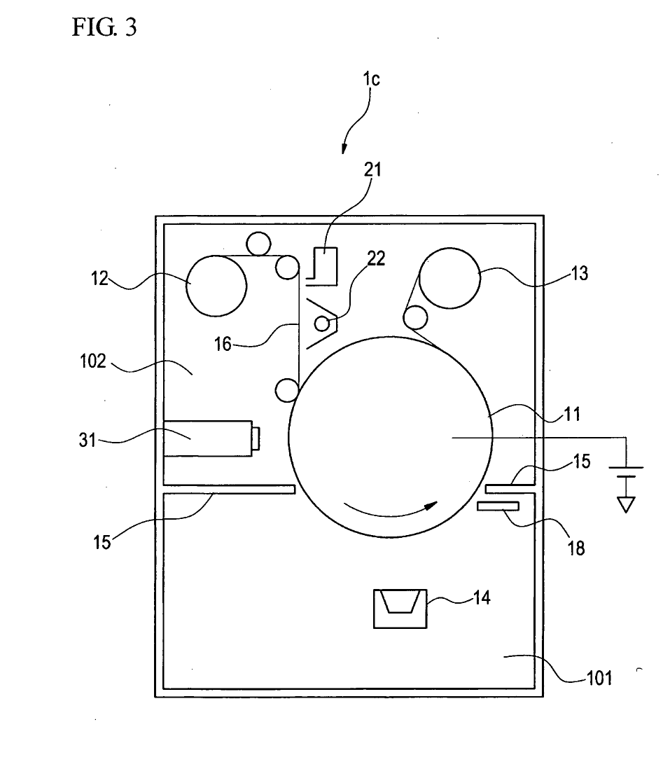

The application of a voltage may be replaced by electron beam irradiation (electron beam shower or EB shower) on the surface B of the substrate film and electrically charging of the evaporation drum with a positive electric potential before formation of the metal-containing evaporation film on the surface B. The method and system structure used in this case are not particularly limited. For example, as shown in FIG. 3, in an evaporation system 1c, an EB showering unit 31 is provided for showering the surface B with electron beams and the evaporation drum 11 is electrically charged with a positive electric potential.

In this case, the metal-containing evaporation film on the surface A side needs to be electrically conductive and, specifically, it is preferable that the metal-containing evaporation film on the surface A side is not higher than 10⁵Ω in terms of sheet resistance.

Incidentally, the concept of the invention further includes a double-sided evaporation film intermediate having a metal-containing evaporation film and an organic substance film on one surface (surface A) of a non-magnetic plastic substrate film in this order in view from the substrate film side, and a double-sided evaporation film manufactured by the manufacturing method according to the invention, having metal-containing evaporation films on both surfaces of a non-magnetic plastic substrate film and further having an organic substance film on the metal-containing evaporation film on one surface (surface A).

Embodiments of the invention will be described below more specifically. Incidentally, the contents which will be described hereinafter may be changed without departing from the spirit of the invention, and the invention need not be limited to the following embodiments.

### Embodiment 1

An evaporation system la shown in FIG. 1 was used. A 50 nm-thick Al film was evaporated on one surface (surface A) of a 5 μm-thick polyester film used as a substrate film 16. When the temperature of an evaporation drum 11 was set at −20° C., evaporation could be made at a film conveyance speed of 200 m/min. When a bias of 100V was further applied between the Al film and the evaporation drum 11 by a method not shown but described in an embodiment of JP-A-2005-146401, evaporation could be made at a film conveyance speed of 300 m/min without thermal deformation of the film.

Successively, a lauryl acrylate monomer from a monomer evaporation source 21 was evaporated on the Al film on the surface A side so that the thickness of the formed film became 100 nm. Then, the monomer was irradiated with UV rays by a UV ray irradiation unit 22 so that the monomer was cured to form an organic substance film. While the substrate film was wound on the cooling drum 11 set at −20° C., a 50 nm-thick Al film was evaporated on the other surface (surface B). Consequently, evaporation could be made at a film conveyance speed of 200 m/min. The lauryl acrylate-cured surface was smoother in terms of surface roughness than the original film surface.

### Embodiment 2

An evaporation system 1b shown in FIG. 2 was used. An Al film was evaporated on the surface A side of a substrate film 16 in the same manner as in Embodiment 1.

Successively, pyromellitic anhydride (PMDA) and bis(4-aminophenyl)ether (ODA) from monomer evaporation sources 23 for evaporating two or more kinds of monomers were evaporated on the Al film on the surface A side to provide a polymer layer so that the thickness of the formed layer became 100 nm. While the substrate film was wound on the cooling drum 11 set at −20° C., a 50 nm-thick Al film was evaporated on the surface B. Consequently, evaporation could be made at a film conveyance speed of 200 m/min.

### Embodiment 3

Evaporation was made in the same manner as in Embodiment 1 except that a bias of 50V was applied between a guide roller 17 and the evaporation drum 11 when the 50 nm-thick Al film was evaporated on the surface B after the organic substance film was formed on the Al film on the surface A side of the substrate film 16. Consequently, the Al film could be evaporated on the surface B at a film conveyance speed of 250 m/min. The lauryl acrylate-cured surface was smoother in terms of surface roughness than the original film surface.

### Embodiment 4

Evaporation was made in the same manner as in Embodiment 1 except that the 50 nm-thick Al film on the surface B was showered with electron beams (acceleration voltage: 1500V at 300 mA) by an EB showering unit 31 and a bias voltage of 200V was applied to the evaporation drum 11 to electrically charge the surface of the evaporation drum 11 with a positive electric potential when the 50 nm-thick Al film was evaporated on the surface B by the EB showering unit 31 after the organic substance film was formed on the Al film on the surface A side of the substrate film 16. Consequently, the Al film could be evaporated on the surface B at a film conveyance speed of 250 m/min without thermal deformation of the substrate film or the like.

### Comparative Example

Evaporation was made in the same manner as in Embodiment 1 except that the organic substance film was not formed on the Al film on the surface A side of the substrate film 16. Consequently, when the Al film was evaporated on the surface B, deformation of the substrate film caused by heat was not observed at a film conveyance speed of 150 m/min but deformation of the substrate film caused by heat was observed at a film conveyance speed of 170 m/min.

1. A method for producing a double-sided evaporation film by forming metal-containing evaporation films on both surfaces of a non-magnetic plastic substrate film by an evaporation system with an evaporation drum, the method comprising, in the following order:
forming a metal-containing evaporation film on a first surface of the substrate film;
forming an organic substance film on the metal-containing evaporation film; and
forming a metal-containing evaporation film on a second surface of the substrate film, the second surface being opposite to the first surface.

2. The method for producing a double-sided evaporation film according to claim 1, wherein a voltage is applied between the metal-containing evaporation film formed on the first surface and the evaporation drum when the metal-containing evaporation film is formed on the second surface.

3. The method for producing a double-sided evaporation film according to claim 1, wherein the second surface of the substrate film, before the formation of the metal-containing evaporation film onto the second surface, is irradiated with an electron beam and the evaporation drum is charged with a positive electric potential when the metal-containing evaporation film is formed on the second surface.

4. The method for producing a double-sided evaporation film according to claim 2, wherein the metal-containing evaporation film on the first surface has a sheet resistance of not higher than 10⁵Ω.

5. The method for producing a double-sided evaporation film according to claim 1, wherein the metal-containing evaporation film comprises a metal or a metal compound.

6. The method for producing a double-sided evaporation film according to claim 1, wherein the organic substance film is formed before the metal-containing evaporation film on the first surface comes into contact with the evaporation drum on a path of conveyance of the substrate film in the evaporation system.

7. The method for producing a double-sided evaporation film according to claim 1, wherein the organic substance film is formed in such a manner that an organic compound is vapor-deposited on the metal-containing evaporation film on the first surface.

8. The method for producing a double-sided evaporation film according to claim 7, wherein the organic compound vapor-deposited on the metal-containing evaporation film on the first surface is an ultraviolet ray- or electron beam-polymerizable organic compound which is irradiated with an ultraviolet ray or an electron beam after the organic compound is vapor-deposited.

9. A double-sided evaporation film intermediate comprising, in the following order: a non-magnetic plastic substrate film; a metal-containing evaporation film; and an organic substance film.

10. A double-sided evaporation film comprising, in the following order:
an organic substance film;
a first metal-containing evaporation film;
a non-magnetic plastic substrate film; and
a second metal-containing evaporation film.

11. A double-sided evaporation film produced by a method comprising forming metal-containing evaporation films on both surfaces of a non-magnetic plastic substrate film by an evaporation system with an evaporation drum, the method comprising, in the following order:
forming a metal-containing evaporation film on a first surface of the substrate film;
forming an organic substance film on the metal-containing evaporation film; and
forming a metal-containing evaporation film on a second surface of the substrate film, the second surface being opposite to the first surface.

12. The method for producing a double-sided evaporation film according to claim 1, which is a method for producing a support for a magnetic recording medium.

13. A support for a magnetic recording medium, which is produced by a method, comprising forming metal-containing evaporation films on both surfaces of a non-magnetic plastic substrate film by an evaporation system with an evaporation drum, the method comprising, in the following order:
forming a metal-containing evaporation film on a first surface of the substrate film;
forming, an organic substance film on the metal-containing evaporation film; and
forming a metal-containing evaporation film on a second surface of the substrate film, the second surface being opposite to the first surface.
